(19) United States
(12) Patent Application Publication
(10) Pub. No.: US 2026/0114053 A1
(43) Pub. Date: Apr. 23, 2026

(54) SEMICONDUCTOR DEVICE INCLUDING ELECTRICAL STRESS PROTECTION CIRCUIT

(71) Applicant: Samsung Electronics Co., Ltd., Suwon-si (KR)

(72) Inventors: Chang-Ju LEE, Suwon-si (KR); Changsoo Kim, Suwon-si (KR)

(73) Assignee: Samsung Electronics Co., Ltd., Suwon-si (KR)

(21) Appl. No.: 19/364,727

(22) Filed: Oct. 21, 2025

(30) Foreign Application Priority Data
Oct. 22, 2024 (KR) 10-2024-0145042
Dec. 13, 2024 (KR) 10-2024-0186493

(51) Int. Cl. H10D 89/60

(52) U.S. Cl. CPC H10D 89/711

(57) ABSTRACT

A semiconductor device including a semiconductor substrate of a first conductivity type; a first electrode electrically connected to an input pad; first doped regions of a second conductivity type electrically connected to the first electrode through first contact plugs, and spaced apart from each other in a first direction horizontal to a plane of the semiconductor substrate; second doped regions of the second conductivity type spaced apart from respective ones of the first doped regions in a second direction perpendicular to the first direction; and a second electrode electrically connected to each of the second doped regions through second contact plugs, the second electrode being electrically connected to a ground electrode. The second electrode overlaps at least portions of a depletion region between the first doped regions and the semiconductor substrate in a third direction perpendicular to the plane of the semiconductor substrate.

### CROSS-REFERENCE TO RELATED APPLICATION(S)

This U.S. non-provisional application claims priority under 35 USC § 119 to Korean Patent Application No. 10-2024-0145042, filed on Oct. 22, 2024, and Korean Patent Application No. 10-2024-0186493, filed on Dec. 13, 2024, in the Korean Intellectual Property Office, the disclosures of which are herein incorporated by reference in their entirety.

### BACKGROUND

The present disclosure relates to semiconductor devices including an electrical stress protection circuit and, more particularly to semiconductor devices including a protection circuit having improved functionality to protect internal circuits from electrical stress.

Electrostatic discharge (ESD), overcurrent, voltage spikes, power surges, and voltage surges may occur externally to a semiconductor device. When electrical stress propagates to an internal circuit through an input pad, the internal circuit may malfunction or be damaged.

A semiconductor device may include a protection circuit to protect internal circuits from electrical stress. For example, a protection element may be provided between an input/output pad and an internal circuit of the semiconductor device. The protection element may include an electrical switch circuit having a multi-finger structure to efficiently transfer external electrical stress to a ground electrode without damage to the internal circuit.

### SUMMARY

Some example embodiments provide an electrical stress protection circuit having improved protective functionality in an ultra-fine process.

Some example embodiments provide an electrical stress protection circuit having improved protective functionality by limiting and/or preventing the degradation of charge flow caused by an electric field of internal interconnections.

Some example embodiments provide a semiconductor device that includes a semiconductor substrate of a first conductivity type; a first electrode electrically connected to an input pad; a plurality of first doped regions of a second conductivity type, the plurality of first doped regions being electrically connected to the first electrode through first contact plugs, and the plurality of first doped regions being spaced apart from each other in a first direction horizontal to a plane of the semiconductor substrate; a plurality of second doped regions of the second conductivity type, the plurality of second doped regions being spaced apart from respective ones of the plurality of first doped regions in a second direction perpendicular to the first direction; and a second electrode electrically connected to each of the plurality of second doped regions through second contact plugs, the second electrode being electrically connected to a ground electrode. The second electrode overlaps at least portions of a depletion region between each of the plurality of first doped regions and the semiconductor substrate in a third direction perpendicular to the plane of the semiconductor substrate.

Some example embodiments further provide a semiconductor device that includes a semiconductor substrate of a first conductivity type; a first electrode electrically connected to an input pad; a plurality of first doped regions of a second conductivity type, the plurality of first doped regions being electrically connected to the first electrode through first contact plugs, and the plurality of first doped regions being spaced apart from each other in a first direction horizontal to a plane of the semiconductor substrate within an active region of the semiconductor substate; a plurality of second doped regions of the second conductivity type, the plurality of second doped regions being spaced apart from respective ones of the plurality of first doped regions in a second direction perpendicular to the first direction; a second electrode electrically connected to each of the plurality of second doped regions through second contact plugs, the second electrode being electrically connected to a ground electrode; and a third electrode electrically connected to the ground electrode. In a third direction, the third electrode overlaps at least portions of a depletion region between each of the plurality of first doped regions and the semiconductor substrate. The third electrode is spaced apart from the second electrode, and the third direction is perpendicular to the plane of the semiconductor substrate.

Some example embodiments still further provide a semiconductor device that includes an electrical stress protection circuit; and an internal circuit. The electrical stress protection circuit includes a plurality of bipolar junction transistors connecting an input pad and a ground electrode in parallel; and a plurality of electrodes. Each of the plurality of bipolar junction transistors includes a region of a semiconductor substrate as a base, the region of the semiconductor substrate having a first conductivity type; a first doped region of a second conductivity type as a collector; and a second doped region of the second conductivity type as an emitter. The plurality of electrodes include a first electrode electrically connected to the input pad and the first doped region; and a second electrode electrically connected to the ground electrode and the second doped region. The second electrode overlaps at least a portion of a depletion region of each of the plurality of bipolar junction transistors in a direction perpendicular to a plane of the semiconductor substrate.

### BRIEF DESCRIPTION OF DRAWINGS

FIG. 1 is an equivalent circuit diagram of a protection circuit according to some example embodiments of the inventive concepts.

FIG. 2 is a diagram illustrating a layout of a protection circuit according to some example embodiments of the inventive concepts.

FIG. 3 is a layout diagram of a protection circuit according to some example embodiments of the inventive concepts.

FIG. 4 is a conceptual cross-sectional view taken along line A-A′ of the layout illustrated in FIG. 3.

FIG. 5 is a diagram illustrating a layout according to a comparative example.

FIG. 6 is a conceptual cross-sectional view taken along line B-B′ of the layout illustrated in FIG. 5.

FIG. 7 is a diagram illustrating a layout according to a comparative example.

FIG. 8 is a conceptual cross-sectional view taken along line C-C′ of the layout illustrated in FIG. 7.

FIG. 9 is a layout diagram of a protection circuit according to some example embodiments of the inventive concepts.

FIG. 10 is a conceptual cross-sectional view taken along line A-A′ of the layout illustrated in FIG. 9.

FIG. 11 is a layout diagram of a protection circuit according to some example embodiments of the inventive concepts.

FIG. 12 is an enlarged view of a portion of the layout illustrated in FIG. 11.

FIG. 13 is a layout diagram of a protection circuit according to some example embodiments of the inventive concepts.

FIG. 14 is a conceptual cross-sectional view taken along line A3-A3′ of the layout illustrated in FIG. 13.

### DETAILED DESCRIPTION

Hereinafter, some example embodiments will be described with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

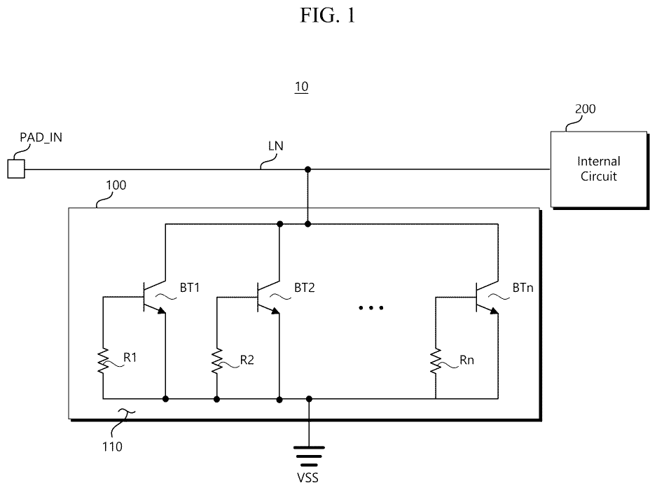

FIG. 1 is a diagram illustrating a semiconductor device 10 according to some example embodiments.

The semiconductor device 10 may include an electrical stress protection circuit 100 and an internal circuit 200. Hereinafter, an electrical stress protection circuit may be referred to as a protection circuit.

The semiconductor device 10 may be implemented as for example various types of processors, including, but not limited to, an application processor, a graphics processor, or a communication processor.

The internal circuit 200 may include a logic circuit. For example, the internal circuit 200 may be an electronic circuit performing logical operations on logical input values to obtain logical output values. The internal circuit 200 may include transistors. For example, the internal circuit 200 may include at least one metal-oxide-semiconductor field-effect transistor (MOSFET).

The protection circuit 100 may include a plurality of bipolar junction transistors BJTs denoted as BT1, BT2 to BTn. In some example embodiments, the bipolar junction transistors BT1, BT2 to BTn may be NPN-type bipolar junction transistors.

The protection circuit 100 may have a multi-finger structure.

For example, each of the bipolar junction transistors BT1, BT2 to BTn may be connected in parallel between an input pad PAD_IN and a ground electrode VSS. Electrical path lengths between the input pad PAD_IN and the ground electrode VSS for each of the bipolar junction transistors BT1, BT2 to BTn may be substantially similar to one another.

The input pad PAD_IN may receive an external input signal, and the input signal may be transmitted to the internal circuit 200 through an internal wiring LN.

When an electrical stress of a magnitude sufficient to induce avalanche breakdown in the bipolar junction transistors BT1, BT2 to BTn is applied externally, a portion or all of the bipolar junction transistors BT1, BT2 to BTn connected in parallel may be turned on. Electrical stress may be transmitted to the ground electrode VSS through each of the turned-on bipolar junction transistors BT1, BT2 to BTn.

The electrical stress may include electrostatic discharge (ESD), overcurrent, voltage spikes, power surges, or voltage surges. The electrical stress may include electrical overstress (EOS). The electrical stress may include external voltage surges such as lightning or electromagnetic waves.

A collector of each of the bipolar junction transistors BT1, BT2 to BTn may be electrically connected to the input pad PAD_IN. An emitter of each of the bipolar junction transistor BT1, BT2 to BTn may be electrically connected to the ground electrode VSS. A substrate 110 may function as a base of each of the bipolar junction transistor BT1, BT2 to BTn. In some example embodiments, the substrate 110 may be a semiconductor substrate.

The substrate 110 may have parasitic resistance. The substrate 110 may function as resistors R1, R2 to Rn connecting the base and the emitter of each of the bipolar junction transistor BT1, BT2 to BTn.

The operation of the bipolar junction transistors BT1, BT2 to BTn in the protection circuit 100 will now be described below in detail.

When electrical stress is introduced from the input pad PAD_IN, a voltage between the collector of each of the bipolar junction transistors BT1, BT2 to BTn and the substrate 110 may be increased. Due to the increased voltage between the substrate 110, which functions as the base, and the collector, avalanche breakdown may occur in the bipolar junction transistors BT1, BT2 to BTn. When a base-emitter voltage exceeds a base-emitter threshold voltage due to rapidly increased current caused by the avalanche breakdown, the bipolar junction transistors BT1, BT2 to BTn may be turned on, and the electrical stress introduced into the input pad PAD_IN may be transmitted to the ground electrode VSS through the bipolar junction transistors BT1, BT2 to BTn.

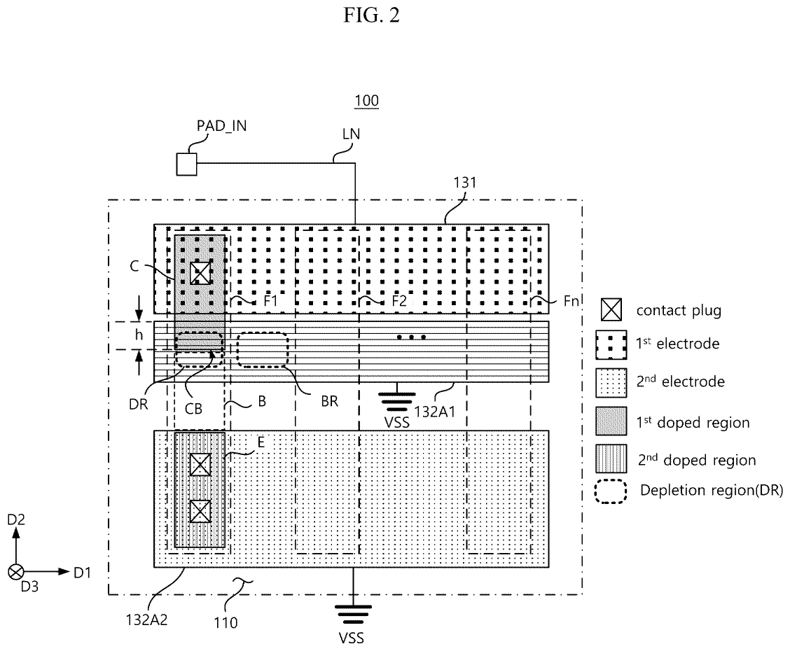

FIG. 2 is a diagram illustrating a conceptual layout of a protection circuit 100 according to some example embodiments. The protection circuit 100 of FIG. 2 may correspond to the protection circuit 100 of FIG. 1. For example, the bipolar junction transistors BT1, BT2 to BTn and electrodes of the protection circuit 100 of FIG. 1 may be implemented based on the layout illustrated in FIG. 2.

Referring to FIG. 2, the protection circuit 100 may include a semiconductor substrate 110 of a first conductivity type, a first electrode 131 electrically connected to an input pad, at least one second electrode 132A1 and 132A2 electrically connected to a ground electrode, a plurality of first doped regions C of a second conductivity type, and a plurality of second doped regions E of the second conductivity type. In some example embodiments, the first conductivity type may be P-type. The substrate 110 may be a P-type substrate 110. The second conductivity type may be N-type. The first doped regions C and the second doped regions E may be formed in an active region of the substrate 110.

The protection circuit 100 may include a plurality of bipolar junction transistors BT1, BT2 to BTn. The bipolar junction transistors BT1, BT2 to BTn may be disposed based on a multi-finger structure including multiple fingers F1, F2 to Fn. For example, each of the bipolar junction transistors BT1, BT2 to BTn of FIG. 1 may be disposed in parallel between the first electrode 131 and at least one second electrode 132A1 and 132A2. An example is provided in which doped regions (e.g., a first doped region C and a second doped region E), respectively functioning as a collector and an emitter of each of the bipolar junction transistor BT1, BT2 to BTn of FIG. 1, may be formed in each of the multi-fingers F1, F2 to Fn.

FIG. 2 illustrates only the doped regions C and E of the first finger F1 in detail, but the doped regions of the other fingers F2 to Fn may be implemented in the same manner as the first finger F1. Although not shown in detail for the purpose of simplifying the drawings, the example described with reference to FIG. 2 is provided in which doped regions C and E, respectively functioning as a collector and an emitter of each of the bipolar junction transistors BT1, BT2 to BTn of FIG. 1, are formed in each of the multi-fingers F1, F2 to Fn.

Each of the plurality of first doped regions C of the second conductivity type and the plurality of second doped regions E of the second conductivity type may respectively function as a collector and an emitter of each of the bipolar junction transistor BT1, BT2 to BTn. The semiconductor substrate 110 of the first conductivity type may function as a base of each of the bipolar junction transistor BT1, BT2 to BTn.

The protection circuit 100 may include a plurality of interconnection electrodes in addition to the first electrode 131 and at least one second electrode 132A1 and 132A2. In FIG. 2, interconnection electrodes between the input pad PAD_IN and the first electrode 131, corresponding to electrodes other than the at least one second electrode 132A1 and 132A2, are schematically represented as an interconnection LN.

In some example embodiments, the first electrode 131 and the at least one second electrode 132A1 and 132A2 may be formed in the same layer. For example, the first electrode 131 and the at least one second electrode 132A1 and 132A2 may be disposed in a first metal interconnection layer from among a plurality of metal interconnection layers overlapping the substrate 110. The first metal interconnection layer may be a metal interconnection layer closest to the substrate 110.

In some example embodiments, the first electrode 131 and the at least one second electrode 132A1 and 132A2 may be formed in different layers. For example, the at least one second electrode 132A1 and 132A2 may be disposed in the first metal interconnection layer, and the first electrode 131 may be disposed in a second metal interconnection layer from among the plurality of metal interconnection layers. The first metal interconnection layer may be a metal interconnection layer closest to the substrate 110. The second metal interconnection layer may be disposed further above the substrate 110 than the first metal interconnection layer.

The first electrode 131 may be formed to extend in a first direction D1. Thus, the first electrode 131 may overlap at least a portion of substrate regions between the plurality of first doped regions C in a third direction D3.

The second electrodes 132A1 and 132A2 may be formed to extend in a first direction D1.

The at least one second electrode 132A1 and 132A2 may have the same or substantially the same spacing from the first electrode 131 in the second direction D2. For example, the spacing between the first electrode 131 in the second direction D2 may be substantially uniform. For example, the at least one second electrode 132A1 and 132A2 may extend parallel to the first electrode 131 in the first direction D1.

An additional interconnection electrode, electrically connecting the input pad PAD_IN and the first electrode 131, may be disposed in a layer at or above the second metal interconnection layer disposed farther from the substrate 110.

Alternatively, the input pad PAD_IN may be directly electrically connected to the first electrode 131.

Each of the first doped regions C may be connected to the first electrode 131 through each first contact plug. The first electrode 131 may be formed as a single electrode or additional electrodes.

The first doping regions C may be formed in the active region of the substrate 110 to be spaced apart from each other in the first direction D1, horizontal to a plane of the substrate 110. The first doping regions C may be disposed to be spaced apart from each other in the first direction D1.

The second doped regions E may be formed in the active region of the substrate 110 to be spaced apart from each other in the first direction D1, horizontal to the plane of the substrate 110. The second doped regions E may be disposed to be spaced apart from each other in the first direction D1.

In the present specification, the first direction D1 and the second direction D2 are parallel to the plane of the substrate 110 and perpendicular to each other. The third direction D3 is perpendicular to the first direction D1 and the second direction D2, and is oriented inwardly of the substrate 110.

Each of the second doped regions E may be connected to at least one second electrode 132A1 and 132A2 through each second contact plug. The second electrodes 132A1 and 132A2 may be electrically connected to the ground electrode VSS. The second electrodes 132A1 and 132A2 may be formed as a single electrode or as additional electrodes. Each of the second electrodes 132A1 and 132A2, including a plurality of electrodes, may be electrically connected to the ground electrode VSS.

Some example embodiments are not limited to the second electrode 132A1 and 132A2 including a plurality of electrodes. For example, the second electrodes 132A1 and 132A2 may be formed as a single physical structure, physically connected to each other in the same process. In FIG. 2, an example is provided in which the second electrodes 132A1 and 132A2 include a plurality of electrodes, and at least one of the second electrodes 132A1 and 132A2 is electrically connected to the second doped regions E.

In some example embodiments, the at least one second electrode 132A1 and 132A2 of the protection circuit 100 may be disposed to overlap at least a portion of the depletion region DR between each of the plurality of first doped regions C and the substrate 110 when viewed in the third direction D3.

In some example embodiments, the at least one second electrode 132A1 and 132A2 may be disposed above at least a portion of the depletion region DR between each of the plurality of first doped regions C and the substrate 110 when viewed in the third direction D3.

In the present specification, an upper portion of the substrate 110 refers to a direction away from the substrate 110 in the third direction D3, while a lower portion of the substrate 110 refers to a direction oriented inwardly of the substrate 110 in the third direction D3.

In some example embodiments, the at least one second electrode 132A1 and 132A2 may be disposed to overlap at least a portion of a boundary CB between each of the plurality of first doped regions C and the substrate 110 when viewed in the third direction D3. The boundary CB may be a boundary between a collector C and a base B of each of the multi-fingers F1, F2 to Fn. A boundary of at least one second electrode 132A1 and 132A2 may be disposed at a position spaced apart by a certain distance h from the boundary CB between the collector C and the base B in an inward direction of the first doping regions C.

For example, when viewed in the third direction D3, at least a portion of the depletion region DR between the collector C and the base B of each of the multi-fingers F1, F2 to Fn may be disposed to overlap the at least one second electrode 132A1 and 132A2.

An electric field may be formed between the first electrode 131 and the at least one second electrode 132A1 and 132A2 disposed above the depletion region DR. Alternatively, an electric field may be formed between the interconnection electrode LN and the at least one second electrode 132A1 and 132A2. Thus, an electric field radiated from the first electrode 131, or from the interconnection electrode LN between the input pad PAD_IN and the first electrode 131, may be blocked by the at least one second electrode 132A1 and 132A2 disposed above the depletion region DR.

Accordingly, the electric field radiated from the first electrode 131 or from the interconnection electrode LN between the input pad PAD_IN and the first electrode 131 does not affect the depletion region DR. As a result, a flow of charges causing avalanche breakdown may not be disturbed by the electric field radiated from the first electrode 131 or from the interconnection electrode LN between the input pad PAD_IN and the first electrode 131.

When the protection circuit is implemented using an ultra-fine process, a spacing between components of the protection circuit may decrease and an impact of the electric field, formed by electrical stress received through the input pad, on the depletion region may increase. The increased electric field may affect the flow of charges and reduce the occurrence of avalanche breakdown. As a result, when the bipolar junction transistor is not turned on, the electrical stress may be transmitted to the internal circuit rather than to the ground electrode.

Because of the above described configuration of some example embodiments of the inventive concepts which include the depletion region DR between the collector C and the base B disposed to be overlapped by at least one second electrode 132A1 and 132A2, even when the protection circuit 100 is implemented using an ultra-fine process, the flow of charges causing avalanche breakdown may not be disturbed and the bipolar junction transistors BT1, BT2 to BTn of FIG. 1 implemented with multi-fingers F1, F2 to Fn may be stably turned on. As a result, the electrical stress received at the input pad PAD_IN may be stably and/or efficiently transmitted to the ground electrode VSS and the internal circuit may be protected.

In some example embodiments, at least one second electrode 132A1 and 132A2 may be disposed to overlap at least a portion of the region BR adjacent to the boundary CB between each of the plurality of first doped regions C and the substrate 110 in the first direction D1 when viewed in the third direction D3. The at least one second electrode 132A1 and 132A2 may be disposed to overlap at least a portion of the region BR adjacent to the boundary CB between the collector C and the base B of each of the multi-fingers F1, F2 to Fn in the first direction D1.

The charges causing avalanche breakdown may move not only through a lower portion (the interior of the substrate 110) of the first doped regions C functioning as a collector, but also through the interior of the substrate 110 in the region BR adjacent to the boundary CB between the collector C and the base B in the first direction D1.

The at least one second electrode 132A1 and 132A2 may block electric fields radiated from the first electrode 131 or from the interconnection electrode LN between the input pad PAD_IN and the first electrode 131 from being formed in the region BR. As a result, the bipolar junction transistors BT1, BT2 to BTn implemented as multi-finger structures including multi-fingers F1, F2 to Fn of FIG. 1 may be turned on more stably.

The at least one second electrode 132A1 and 132A2 may be disposed above at least a portion of the plurality of second doped regions E when viewed in the third direction D3. The at least one second electrode 132A1 and 132A2 may overlap the plurality of second doped regions E when viewed in the third direction D3.

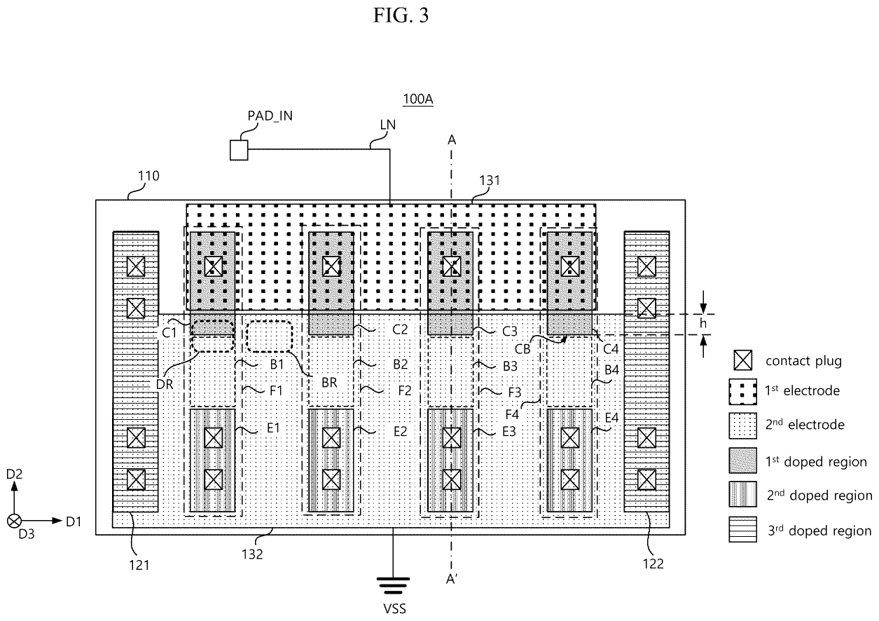

FIG. 3 is a layout diagram of a protection circuit 100A according to some example embodiments. The protection circuit 100A of FIG. 3 may correspond to the protection circuit 100 of FIG. 1.

The protection circuit 100A will now be described below with reference to FIG. 3. Details redundant or similar to the embodiment described with reference to FIG. 2 will be omitted.

FIG. 3 illustrates an example in which a protection circuit 100A includes four multi-fingers F1, F2, F3, and F4. Alternatively, the protection circuit 100A may include five or more multi-fingers. Each of the multi-fingers F1, F2, F3, and F4 may include a bipolar junction transistor of FIG. 1.

Referring to FIG. 3, the protection circuit 100A may include a semiconductor substrate 110 of a first conductivity type, a first electrode 131, a second electrode 132, a plurality of first doped regions C of a second conductivity type, a plurality of second doped regions E of the second conductivity type, and at least one third doped region 121 and 122 of the first conductivity type. The third doped regions 121 and 122 may be doped at a higher concentration than the semiconductor substrate 110. In some example embodiments, the first conductivity type may be P-type. The substrate 110 may be a P-type substrate 110. The second conductivity type may be N-type.

The first electrode 131 may be electrically connected to an input pad, and the second electrode 132 may be electrically connected to a ground electrode VSS and a second doped regions E.

Unlike the embodiment of FIG. 2, the second electrode 132 of the protection circuit 100A may be formed as a single electrode. When viewed in a third direction D3, the second electrode 132 may overlap the second doped regions E1, E2, E3, and E4 of each of the multi-fingers F1, F2, F3, and F4, and the substrate regions B1, B2, B3, and B4 acting as a base. When viewed in a third direction D3, the second electrode 132 may overlap at least a portion of the first doped regions C1, C2, C3, and C4 of each of the multi-fingers F1, F2, F3, and F4. For example, a boundary of the second electrode 132 may be disposed at a certain distance h away from a boundary CB between each of the first doping regions C1, C2, C3, and C4 and each of the substrate regions B in an inward direction of the first doping regions C.

The protection circuit 100A may be electrically connected to the ground electrode VSS and include at least one third doping region 121 and 122 of the first conductivity type with a higher concentration than the substrate 110.

The third doped regions 121 and 122 may extend in the second direction D2 and be disposed at the periphery of the multi-fingers F1, F2, F3, and F4.

The second electrode 132 may overlap at least a portion of the third doped regions 121 and 122 when viewed in the third direction D3. The third doped regions 121 and 122 may be electrically connected to the second electrode 132 through contact plugs.

The third doped regions 121 and 122 may function as pickup regions for picking up a voltage at the ground electrode VSS. The substrate 110 may be connected to the ground electrode VSS through the third doped regions 121 and 122 to be rapidly set to the voltage at the ground electrode VSS.

Similarly to the protection circuit 100 of FIG. 2, the second electrode 132 of the protection circuit 100A may protect the depletion region DR between each of the first doped regions C1, C2, C3, and C4 and each of the second doped regions E1, E2, E3, and E4 from an electric field. The second electrode 132 may also protect the region BR adjacent to the depletion region DR in the first direction D1 from an electric field.

Thus, the bipolar junction transistors of the multi-fingers F1, F2, F3, and F4 may be stably turned on by electrical stress and transmit the electrical stress to the ground electrode VSS.

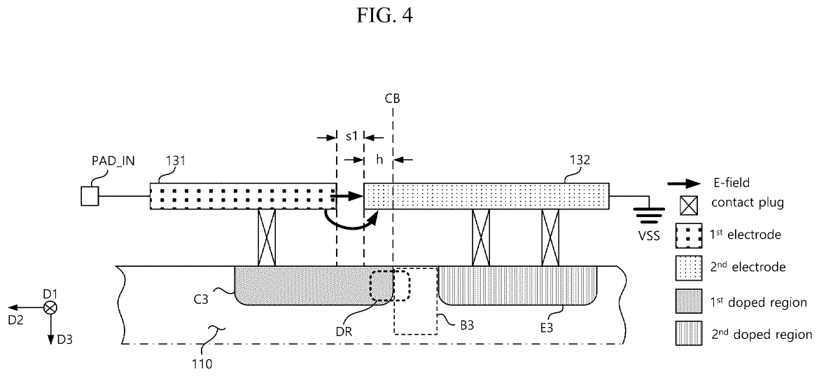

FIG. 4 is a conceptual cross-sectional view taken along line A-A′ of the layout of the protection circuit 100A illustrated in FIG. 3.

Referring to FIG. 4, the second electrode 132 disposed above the second doped region E3 of the third multi-finger F3 overlaps a substrate region B3 in the third direction D3. The second electrode 132 may extend to a position spaced apart by a certain distance h in the second direction D2 from the boundary CB between the first doped region C3 and the substrate region B3 of the third multi-finger F3 of FIG. 3. The second electrode 132 may overlap at least a portion of the first doped region C3 of the third multi-finger F3 in the third direction D3.

The first electrode 131 disposed above the first doped region C3 may be disposed in the same electrode interconnection layer as the second electrode 132 and may be spaced apart from the second electrode 132 by a certain distance s1. For example, the first electrode 131 may be spaced apart from the second electrode 132 by 1 to 3 times the minimum unit of a design rule. The first electrode 131 may not overlap at least a portion of the first doped region C3 of the third multi-finger F3 in the third direction D3.

An electric field radiated from the first electrode 131 may be formed toward the second electrode 132 and may not affect the depletion region DR. Accordingly, the bipolar junction transistor of the multi-finger may be stably turned on by electrical stress.

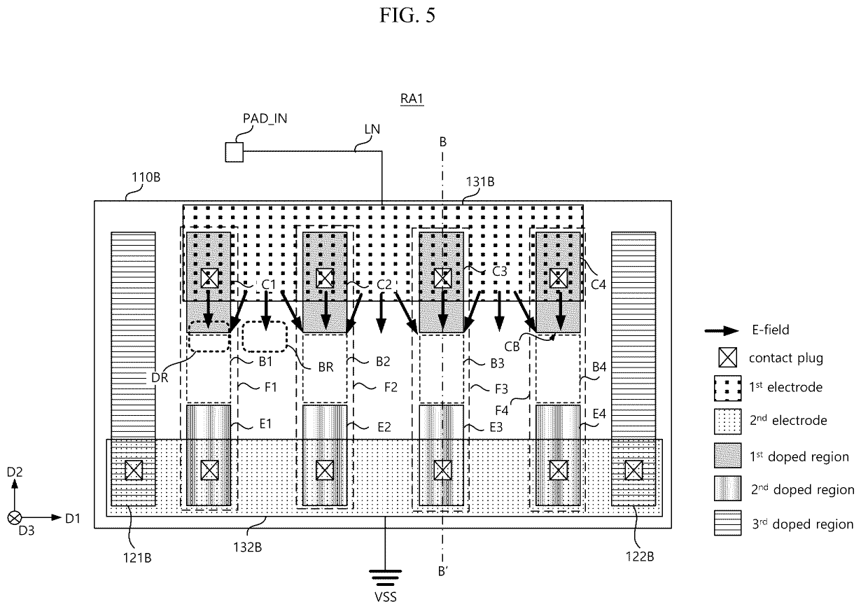

FIG. 5 is a diagram illustrating a layout RA1 according to a comparative example.

The protection circuit RA1 may be a circuit of the comparative example.

The protection circuit RA1 of the comparative example will be described compared to the protection circuits 100 and 100A illustrated in FIG. 2 and FIG. 3.

Referring to FIG. 5, a second electrode 132B may be electrically connected to the second doped regions E1, E2, E3, and E4 and a ground electrode VSS.

Unlike the protection circuits 100 and 100A illustrated in FIG. 2 and FIG. 3, the second electrode 132B of the protection circuit RA1 may not overlap substrate regions B1, B2, B3, and B4 in a third direction D3. The second electrode 132B of the protection circuit RA1 may not overlap first doped regions C1, C2, C3, and C4 in the third direction D3.

For example, the second electrode 132B of the protection circuit RA1 may not protect the depletion region DR, formed in the first doped regions C1, C2, C3, and C4 and the substrate regions B1, B2, B3, and B4, from an electric field. The second electrode 132B of the protection circuit RA1 may not overlap a region BR, adjacent to the depletion region DR in the first direction D1, in the third direction D3. Thus, the second electrode 132B may not protect the region BR from an electric field. As a result, when electrical stress is applied to the protection circuit RA1 formed by an ultra-fine process, a flow of charges in the depletion region DR and the region BR may be affected by the electric field, and avalanche breakdown may not occur. Accordingly, the bipolar junction transistors of the multi-fingers F1, F2, F3, and F4 may not be turned on, and the electrical stress may be transmitted to an internal circuit rather than to the ground electrode VSS.

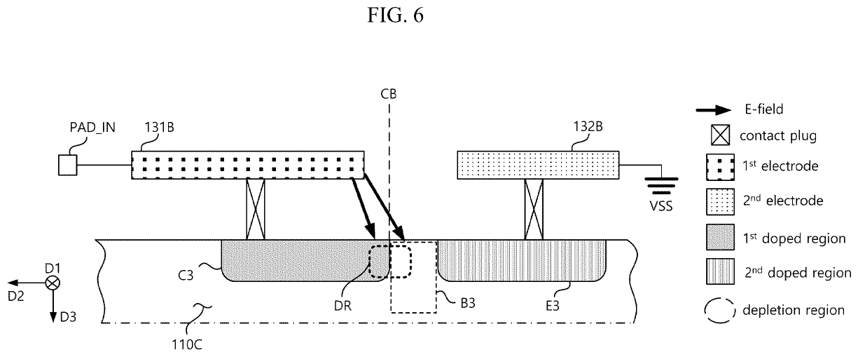

FIG. 6 is a conceptual cross-sectional view taken along line B-B′ of the layout of the protection circuit RA1 illustrated in FIG. 5.

Referring to FIG. 6, the second electrode 132B disposed above the second doped region E3 of the third multi-finger F3 may not overlap the substrate region B3 in the third direction D3. The second electrode 132B may not extend to the boundary CB between the first doped region C3 and the substrate region B3 of the third multi-finger F3 of FIG. 5. Thus, the second electrode 132B may not overlap the depletion region DR in the third direction D3, and the electric field may interfere with a flow of charges in the depletion region DR.

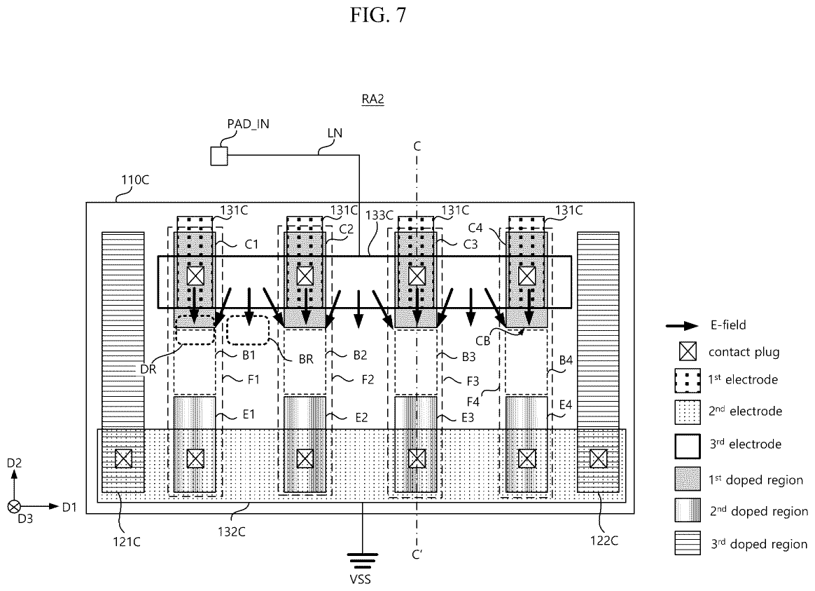

FIG. 7 is a diagram illustrating a layout of a protection circuit RA2 according to another comparative example.

The protection circuit RA2 may be a circuit according to the another comparative example.

The protection circuit RA2 according to the another comparative example will now be described compared to the protection circuits 100 and 100A illustrated in FIGS. 2 and 3. Details redundant or similar to the protection circuit RA1 of FIG. 6 will be omitted.

Referring to FIG. 7, a first electrode 131C may be electrically connected to first doped regions C1, C2, C3, and C4 through first contact plugs. A second electrode 132C may be connected to second doped regions E1, E2, E3, and E4 through second contact plugs. The second electrode 132C may be electrically connected to a ground electrode VSS. The first electrode 131C and the second electrode 132C may be disposed in a first metal interconnection layer.

The protection circuit RA2 may further include a third electrode 133C. The third electrode 133C may be electrically connected to the first electrode 131C, and may be disposed in a second metal interconnection layer. The second metal interconnection layer may be disposed further above the substrate 110C than the first metal interconnection layer.

Referring to FIG. 7, the first electrode 131C may include a plurality of electrodes, and each of the plurality of electrodes included in the first electrode 131C may overlap at least a portion of each of the first doped regions C1, C2, C3, and C4 in the third direction D3. Each of the plurality of electrodes included in first electrode 131C may be disposed to be spaced apart from each other in the first direction D1.

The third electrode 133C may be formed to extend in the first direction D1 to connect each of the first electrodes 131C, spaced apart from each other, to the interconnection electrode LN. The third electrode 133C may overlap the regions between the first electrodes 131C disposed to be spaced apart from each other in the third direction D3.

Accordingly, the substrate region BR adjacent to the depletion region DR in the first direction D1 may experience a larger electric field than the protection circuit RA1 of FIG. 5. The depletion region DR of the first doped regions C1, C2, C3, and C4 and the substrate regions B1, B2, B3, and B4 of each of the multi-fingers F1, F2, F3, and F4 may be affected by an electric field radiated from the first electrode 131C and an electric field radiated from the third electrode 133C. As a result, the protection circuit RA2 formed using an ultra-fine process may exhibit weaker protection functionality than the protection circuit RA1 of FIG. 5.

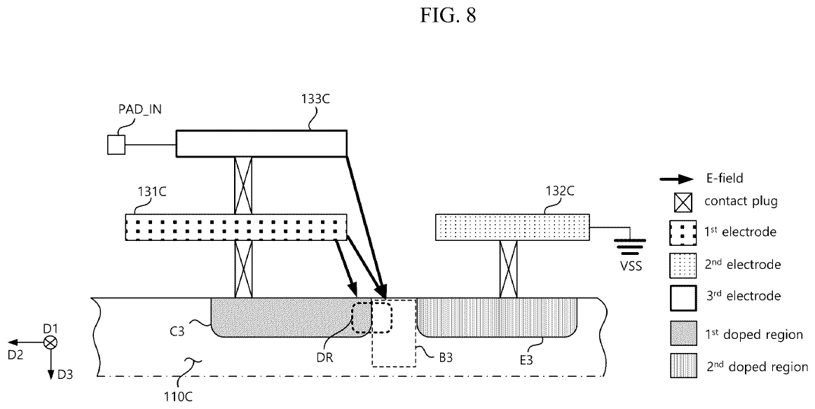

FIG. 8 is a conceptual cross-sectional view taken along line B-B′ of the layout of the protection circuit RA2 illustrated in FIG. 7.

Referring to FIG. 8, the second electrode 132C disposed above the second doped region E3 of the third multi-finger F3 may not overlap the substrate region B3 in the third direction D3. The second electrode 132C may not extend to the boundary CB between the first doped region C3 and the substrate region B3 of the third multi-finger F3 of FIG. 7.

A third electrode 133C electrically connected to an input pad may be disposed above the first electrode 131C.

Accordingly, the second electrode 132C may not overlap a depletion region DR in the third direction D3, and an electric field radiated from the first electrode 131C and the third electrode 133C may interfere with a flow of charges in the depletion region DR.

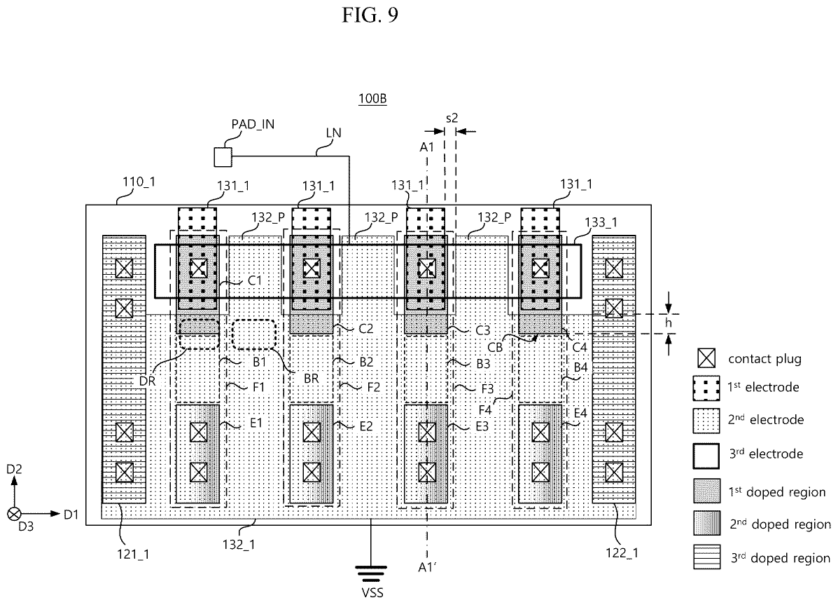

FIG. 9 is a layout diagram of a protection circuit 100B according to some example embodiments. The protection circuit 100B may correspond to the protection circuit 100 of FIG. 1.

The protection circuit 100B according to some example embodiments will now be described with reference to FIG. 9. Details redundant or similar to the protection circuits 100 and 100A of FIGS. 2 and 3 will be omitted.

Referring to FIG. 9, a first electrode 131_1 may be electrically connected to first doped regions C1, C2, C3, and C4 through first contact plugs. The second electrode 132_1 may be connected to second doped regions E1, E2, E3, and E4 through second contact plugs. The second electrode 132_1 may be electrically connected to a ground electrode VSS. The first electrode 131_1 and the second electrode 132_1 may be disposed in a first metal interconnection layer.

The protection circuit 100B may further include a third electrode 133_1. The third electrode 133_1 may be electrically connected to the first electrode 131_1 and disposed in a second metal interconnection layer. The second metal interconnection layer may be disposed further above the substrate 110_1 than the first metal interconnection layer.

Referring to FIG. 9, the first electrode 131_1 may include a plurality of electrodes, and each of the plurality of electrodes included in the first electrode 131_1 may overlap at least a portion of each of the first doped regions C1, C2, C3, and C4 in the third direction D3. Each of the plurality of electrodes included in the first electrode 131_1 may be disposed to be spaced apart from each other in the first direction D1.

The third electrode 133_1 may extend in the first direction D1 to connect each of the plurality of plurality of electrodes included in the first electrodes 131_1 and disposed to be spaced apart from each other, to the interconnection electrode LN. The third electrode 133_1 may overlap regions between the plurality of electrodes included in the first electrodes 131_1 and disposed to be spaced apart from each other in the third direction D3. The third electrode 133_1 may overlap at least a portion of each of the first doped regions C1, C2, C3, and C4 in the third direction D3.

Similarly to the protection circuits 100 and 100A of FIG. 2 and FIG. 3, the second electrode 132_1 according to some example embodiments may overlap at least a portion of each of the first doped regions C1, C2, C3, and C4 in the third direction D3. A boundary of the second electrode 132_1 may be disposed at a distance h away from the boundary CB in an inward direction of the first doped regions C1, C2, C3, and C4.

Unlike the protection circuits 100 and 100A of FIG. 2 and FIG. 3, the second electrode 132_1 may include at least one protrusion 132_P extending in a second direction D2 between the plurality of electrodes included in the first electrodes 131_1.

In some example embodiments, the protrusion 132_P may extend to the boundary of one end of the first doped regions C1, C2, C3, and C4. The boundary of one end of the first doped regions C1, C2, C3, and C4 may be disposed in a direction, opposite to the second doped regions E1, E2, E3, and E4.

In some example embodiments, the protrusion 132_P may extend beyond the boundary CB but may not extend to the boundary of one end of the first doped regions C1, C2, C3, and C4.

In some example embodiments, the protrusion 132_P may overlap the substrate 110_1 in the third direction D3 but may not overlap the first doped regions C1, C2, C3, and C4.

The protrusion 132_P enables the second electrode 132_1 of the protection circuit 100B to more effectively block the electric field radiated from the third electrode 133_1. The protrusion 132_P may more effectively block the electric field radiated to the region BR adjacent to the boundary CB in the first direction D1.

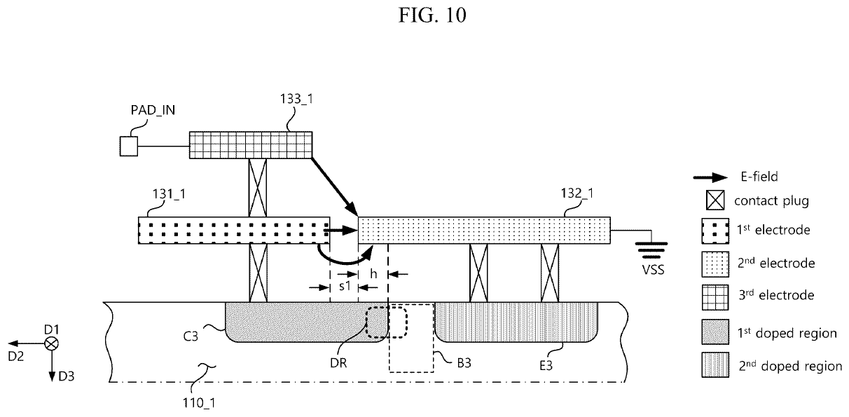

FIG. 10 is a conceptual cross-sectional view taken along line A1-A1′ of the layout of the protection circuit 100B illustrated in FIG. 9. Details redundant or similar to the embodiment described with reference to FIG. 4 will be omitted, while differences from the embodiment of FIG. 4 will be emphasized.

Referring to FIG. 10, the second electrode 132_1 disposed above the second doped region E3 of the third multi-finger F3 may overlap the substrate region B3 in the third direction D3. The second electrode 132_1 may extend to a position spaced a certain distance h along the second direction D2 from the boundary CB between the first doped region C3 and the substrate region B3 of the third multi-finger F3 of FIG. 9. The second electrode 132_1 may overlap at least a portion of the first doped region C3 of the third multi-finger F3 in the third direction D3.

The first electrode 131_1 disposed above the first doped region C3 may be disposed in the same electrode interconnection layer as the second electrode 132_1 and may be spaced apart from the second electrode 132_1 by a certain distance s1.

A third electrode 133_1, electrically connected to the input pad PAD_IN, may be disposed above the first electrode 131_1.

The electric field, radiated from the first electrode 131_1 and the third electrode 133_1, may be blocked by the second electrode 132_1 extending to an upper portion of the first doped region C3 of the third multi-finger F3.

The electric field radiated from the first electrode 131_1 and the third electrode 133_1 may be formed toward the second electrode 132_1 and may not affect the depletion region DR. Thus, the bipolar junction transistor of the multi-finger may be stably turned on by electrical stress.

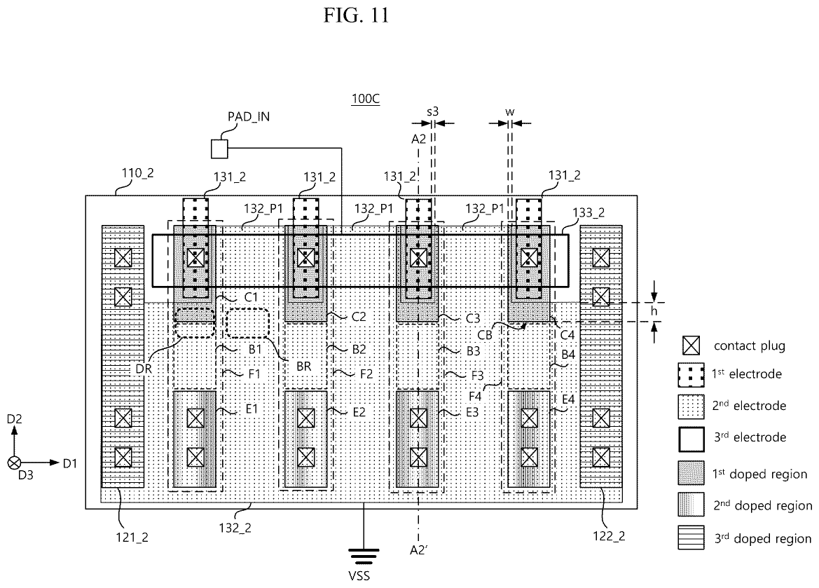

FIG. 11 is a layout diagram of a protection circuit 100C according to some example embodiments. Details redundant or similar to the embodiment described with reference to FIG. 9 will be omitted, while differences from the embodiment of FIG. 9 will be emphasized.

A cross-sectional view taken along line A3-A3′ of the layout of the protection circuit 100C of FIG. 11 may be similar to the cross-sectional view of FIG. 10.

Referring to FIG. 11, similarly to the protection circuit 100B illustrated in FIG. 9, a second electrode 132_2 may include at least one protrusion 132_P1 extending in a second direction D2 between first electrodes 131_2.

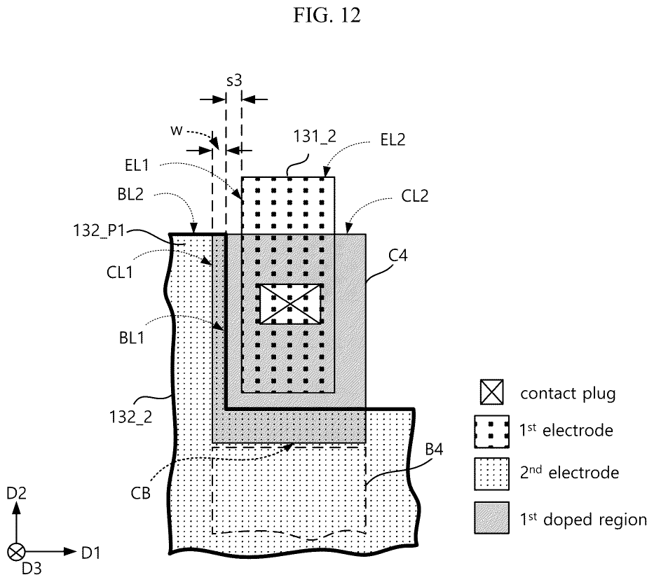

Unlike the protrusion 132_P of FIG. 9, a protrusion 132_P1 of the second electrode 132_2 may extend to an upper portion of first doped regions C1, C2, C3, and C4 in a first direction D1. For example, a boundary of the protrusion 132_P1 in a first direction D1 may overlap at least a portion of the first doped regions C1, C2, C3, and C4 in a third direction D3. This will be described in detail with reference to FIG. 12.

FIG. 12 is an enlarged view illustrating the vicinity of the protrusion 132_P1 illustrated in FIG. 11. For clarity, some components such as the third electrode 133_2 are not illustrated in FIG. 12.

FIG. 12 illustrates the first doped region C4 of the fourth multi-finger F4, the protrusion 132_P1 in the vicinity of the first doped region C4, and the first electrode 131_2 above the first doped region C4.

Referring to FIG. 12, the first electrode 131_2 above the first doped region C4 may include a boundary EL1 in a first direction D1 and a boundary EL2 in a second direction D2. The first doped region C4 may include a boundary CL1 in the first direction D1 and a boundary CL2 in the second direction D2. The protrusion 132_P1 may include a boundary BL1 in the first direction D1 and a boundary BL2 in the second direction D2.

Unlike the protection circuit 100B illustrated in FIG. 9, the protrusion 132_P1 extends inwardly of the first doped region C4. For example, the protrusion 132_P1 extends to a position inside the first doped region C4, spaced a desired (and/or alternatively predetermined) distance w from the boundary CL1 in the first direction D1.

In some example embodiments, the boundary BL1 of the protrusion 132_P1 in the first direction D1 may be disposed to be spaced apart from the boundary EL1 of the first electrode 131_2 in the first direction D1 by a desired (and/or alternatively predetermined) distance s3. For example, the boundary BL1 of the protrusion 132_P1 may be spaced apart from the boundary EL1 of the first electrode 131_2 by 1 to 3 times the minimum unit of a design rule.

The boundary BL1 of the protrusion 132_P1 in the first direction D1 may be disposed above the first doped region C4.

Accordingly, the second electrode 132_2 may significantly reduce an impact of the electric field, radiated from the first electrode 131_2 and the third electrode 133_2 of FIG. 11, on the depletion region DR. As a result, a bipolar junction transistor of a multi-finger may be stably turned on by electrical stress.

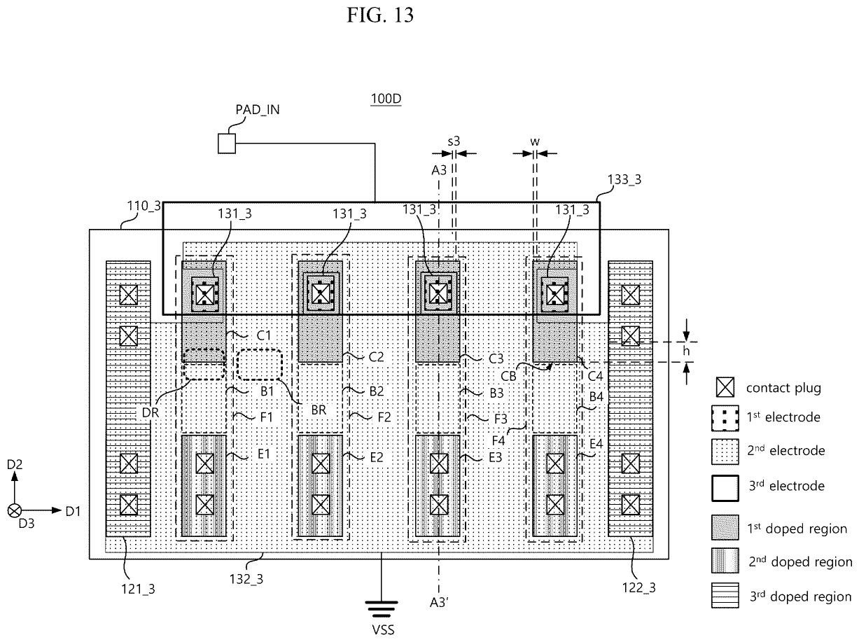

FIG. 13 is a layout diagram of a protection circuit 100D according to some example embodiments.

Details redundant or similar to the embodiments described with reference to FIGS. 9 and 11 will be omitted, while differences from the embodiment of FIGS. 9 and 11 will be emphasized.

Referring to FIG. 13, a first electrode 131_3 may include a plurality of electrodes, and each of the plurality of electrodes included in the first electrode 131_3 may overlap at least a portion of each of first doped regions C1, C2, C3, and C4 in a third direction D3. The plurality of electrodes included in the first electrode 131_3 may be disposed to be spaced apart from each other in a first direction D1.

The second electrode 132_3 may be formed to surround at least three surfaces of each of the plurality of electrodes included in the first electrode 131_3.

At least a portion of the second electrode 132_3 may overlap at least a portion of the third electrode 133_3 in the third direction D3. For example, at least a portion of the second electrode 132_3 surrounding each of the plurality of electrodes included in the first electrode 131_3 may overlap at least a portion of the third electrode 133_3 in the third direction D3.

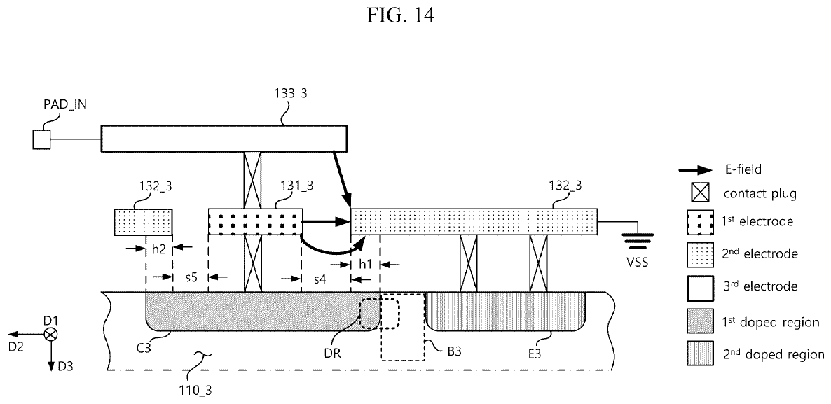

FIG. 14 is a conceptual cross-sectional view taken along line A3-A3′ of the layout 100D illustrated in FIG. 13.

Details redundant or similar to the embodiment described with reference to FIG. 10 will be omitted, while differences from the embodiment of FIG. 10 will be emphasized.

Referring to FIG. 14, the second electrode 132_3 disposed above the second doped region E3 of the third multi-finger F3 may overlap a substrate region B3 in a third direction D3. The second electrode 132_3 may extend in the second direction D2 from the boundary CB between the first doping region C3 of the third multi-finger F3 and the substrate region B3 to a position spaced by a distance h1. The second electrode 132_3 may further extend in a second direction D2 from another boundary of the first doping region C3 to a position spaced by a distance h2. The second electrode 132_3 may overlap at least a portion of the first doping region C3 of the third multi-finger F3 in the third direction D3.

The first electrode 131_3, disposed above the first doping region C3, may be disposed on the same electrode interconnection layer as the second electrode 132_3 and may be spaced from the second electrode 132_3 by desired (and/or alternatively predetermined) distances s4 and s5.

A third electrode 133_3, electrically connected to the input pad PAD_IN, may be disposed above the first electrode 131_3.

At least a portion of the second electrode 132_3 may overlap at least a portion of the third electrode 133_3 in the third direction D3. For example, at least a portion of the second electrode 132_3, extending from another boundary of the first doping region C3 to a position spaced by a distance h2 in the second direction D2, may overlap a portion of the third electrode 133_3 in the third direction D3.

Electric fields, radiated from the first electrode 131_3 and the third electrode 133_3, may be blocked by the second electrode 132_3 surrounding at least three surfaces of the first electrode 131_3 of the third multi-finger F3.

The electric fields, radiated from the first electrode 131_3 and the third electrode 133_3, may be formed toward the second electrode 132_3 and may not affect the depletion region DR. As a result, the bipolar junction transistor of the multi-finger configuration may be stably turned on by electrical stress.

As set forth above, according to some example embodiments, a semiconductor device may provide stable electrical stress protection functionality even when manufactured using an ultra-fine process.

An electrical stress protection circuit of the semiconductor device may limit and/or prevent degradation of a flow of charges caused by an electric field of an internal interconnection of the protection circuit and may stably transmit external electrical stress to a ground electrode.

Some example embodiments of the inventive concepts may further provide a method of manufacturing a semiconductor device including forming a plurality of first doped regions of a second conductivity type in a semiconductor substrate of a first conductivity type, the plurality of first doped regions being spaced apart from each other in a first direction horizontal to a plane of the semiconductor substrate; forming a plurality of second doped regions of the second conductivity type, the plurality of second doped regions being spaced apart from respective ones of the plurality of first doped regions in a second direction perpendicular to the first direction; forming a first electrode over the semiconductor substrate; electrically connecting the first electrode to the plurality of first doped regions and an input pad; forming a second electrode over the semiconductor substrate; and electrically connecting the second electrode to each of the plurality of second doped regions and to a ground electrode. The forming the second electrode includes overlapping the second electrode with at least portions of a depletion region between each of the plurality of first doped regions and the semiconductor substrate in a third direction perpendicular to the plane of the semiconductor substrate.

In some example embodiments of the method of manufacturing a semiconductor device the plurality of first doped regions are formed as respective collectors of bipolar junction transistors, the plurality of second doped regions are formed as respective emitters of the bipolar junction transistors, and the semiconductor substrate is a base of the bipolar junction transistors.

In some example embodiments of the method of manufacturing a semiconductor device, the first electrode and the second electrode are formed in a same layer.

In some example embodiments of the method of manufacturing a semiconductor device, the forming the second electrode includes forming the second electrode in a metal interconnection layer from among a plurality of metal interconnection layers closest to the semiconductor substrate.

In some example embodiments, the method of manufacturing a semiconductor device further includes forming at least one pickup region electrically connected to the ground electrode, the at least one pickup region formed as having the first conductivity type and a doping concentration higher than a doping concentration of the semiconductor substrate, and as extending in the second direction.

In some example embodiments of the method of manufacturing a semiconductor device, the first electrode is formed to extend in the first direction, and in the third direction, the first electrode is formed to overlap at least portions of the semiconductor substrate between the plurality of first doped regions.

In some example embodiments of the method of manufacturing a semiconductor device, the second electrode is formed to extend in the first direction, with a spacing between the first electrode and the second electrode in the second direction being uniform.

In some example embodiments of the method of manufacturing a semiconductor device, in the third direction, the second electrode is formed to overlap at least portions of each of the plurality of first doped regions in the third direction and to overlap each of the plurality of second doped regions in the third direction.

In some example embodiments of the method of manufacturing a semiconductor device, the first electrode is formed as comprising a plurality of electrodes respectively overlapping at least portions of each of the plurality of first doped regions in the third direction, the plurality of electrodes of the first electrode extending in the second direction.

In some example embodiments of the method of manufacturing a semiconductor device, the second electrode is formed as comprising a plurality of protrusions extending in the second direction between the plurality of electrodes of the first electrode.

In some example embodiments of the method of manufacturing a semiconductor device, the plurality of protrusions are formed as overlapping at least portions of the plurality of electrodes of the first electrode in the third direction.

In some example embodiments of the method of manufacturing a semiconductor device, the plurality of protrusions are formed as overlapping the semiconductor substrate in the third direction and not overlapping the plurality of first doped regions in the third direction.

In some example embodiments of the method of manufacturing a semiconductor device, at least first portions of each of the plurality of protrusions of the second electrode are formed as overlapping the semiconductor substrate in the third direction, and at least second portions of each of the plurality of protrusions are formed as overlapping at least a portion of the plurality of first doped regions in the third direction.

In some example embodiments of the method of manufacturing a semiconductor device, the first electrode is formed in a layer farther from the semiconductor substrate than the second electrode in the third direction, and a material of the first electrode is a same material as a material of the second electrode.

In some example embodiments, the method of manufacturing a semiconductor further includes forming a third electrode in a layer farther from the semiconductor substrate than the second electrode in the third direction; and electrically connecting the third electrode to the input pad and the first electrode. At least a portion of the first electrode is formed as overlapping at least a portion of the third electrode in the third direction.

In some example embodiments of the method of manufacturing a semiconductor device, the first electrode is formed as including a plurality of electrodes overlapping at least a portion of each of the plurality of first doped regions in the third direction, and the second electrode is formed as surrounding at least three respective surfaces of each of the plurality of electrodes of the first electrode, when viewed in the third direction.

While some example embodiments have been shown and described above, it will be apparent to those skilled in the art that modifications and variations could be made without departing from the scope of the present inventive concepts as defined by the appended claims.

What is claimed is:

1. A semiconductor device comprising:
a semiconductor substrate of a first conductivity type;
a first electrode electrically connected to an input pad;
a plurality of first doped regions of a second conductivity type, the plurality of first doped regions being electrically connected to the first electrode through first contact plugs, and the plurality of first doped regions being spaced apart from each other in a first direction horizontal to a plane of the semiconductor substrate;
a plurality of second doped regions of the second conductivity type, the plurality of second doped regions being spaced apart from respective ones of the plurality of first doped regions in a second direction perpendicular to the first direction; and
a second electrode electrically connected to each of the plurality of second doped regions through second contact plugs, the second electrode being electrically connected to a ground electrode,
wherein the second electrode overlaps at least portions of a depletion region between each of the plurality of first doped regions and the semiconductor substrate in a third direction perpendicular to the plane of the semiconductor substrate.

2. The semiconductor device of claim 1, wherein
the plurality of first doped regions are respectively configured as collectors of bipolar junction transistors,
the plurality of second doped regions are respectively configured as emitters of the bipolar junction transistors, and
the semiconductor substrate is configured as a base of the bipolar junction transistors.

3. The semiconductor device of claim 1, wherein
the first electrode and the second electrode are in a same layer.

4. The semiconductor device of claim 1, wherein
the second electrode is in a metal interconnection layer from among a plurality of metal interconnection layers closest to the semiconductor substrate.

5. The semiconductor device of claim 1, further comprising:
at least one pickup region electrically connected to the ground electrode, the at least one pickup region having the first conductivity type and a doping concentration higher than a doping concentration of the semiconductor substrate,
wherein the at least one pickup region extends in the second direction.

6. The semiconductor device of claim 1, wherein
the first electrode extends in the first direction, and
in the third direction, the first electrode overlaps at least portions of the semiconductor substrate between the plurality of first doped regions.

7. The semiconductor device of claim 6, wherein
the second electrode extends in the first direction, and
a spacing between the first electrode and the second electrode in the second direction is uniform.

8. The semiconductor device of claim 7, wherein
in the third direction, the second electrode overlaps at least portions of each of the plurality of first doped regions and overlaps each of the plurality of second doped regions.

9. The semiconductor device of claim 1, wherein
the first electrode comprises a plurality of electrodes respectively overlapping at least portions of each of the plurality of first doped regions in the third direction, the plurality of electrodes of the first electrode extending in the second direction.

10. The semiconductor device of claim 9, wherein
the second electrode comprises a plurality of protrusions extending in the second direction between the plurality of electrodes of the first electrode.

11. The semiconductor device of claim 10, wherein
the plurality of protrusions overlap at least portions of the plurality of electrodes of the first electrode in the third direction.

12. The semiconductor device of claim 10, wherein
the plurality of protrusions overlap the semiconductor substrate in the third direction and do not overlap the plurality of first doped regions in the third direction.

13. The semiconductor device of claim 10, wherein
at least first portions of each of the plurality of protrusions of the second electrode overlap the semiconductor substrate in the third direction, and at least second portions of each of the plurality of protrusions overlap at least a portion of the plurality of first doped regions in the third direction.

14. The semiconductor device of claim 1, wherein
in the third direction, the first electrode is in a layer farther from the semiconductor substrate than the second electrode, and a material of the first electrode is a same material as a material of the second electrode.

15. The semiconductor device of claim 1, further comprising:
a third electrode in a layer farther from the semiconductor substrate than the second electrode in the third direction, the third electrode being electrically connected to the input pad and the first electrode,
wherein at least a portion of the first electrode overlaps at least a portion of the third electrode in the third direction.

16. The semiconductor device of claim 15, wherein
the first electrode comprises a plurality of electrodes overlapping at least a portion of each of the plurality of first doped regions in the third direction, and
the second electrode surrounds at least three respective surfaces of each of the plurality of electrodes of the first electrode, when viewed in the third direction.

17. A semiconductor device comprising:
a semiconductor substrate of a first conductivity type;
a first electrode electrically connected to an input pad;
a plurality of first doped regions of a second conductivity type, the plurality of first doped regions being electrically connected to the first electrode through first contact plugs, and the plurality of first doped regions being spaced apart from each other in a first direction horizontal to a plane of the semiconductor substrate within an active region of the semiconductor substrate;
a plurality of second doped regions of the second conductivity type, the plurality of second doped regions being spaced apart from respective ones of the plurality of first doped regions in a second direction perpendicular to the first direction;
a second electrode electrically connected to each of the plurality of second doped regions through second contact plugs, the second electrode being electrically connected to a ground electrode; and
a third electrode electrically connected to the ground electrode,
wherein
in a third direction, the third electrode overlaps at least portions of a depletion region between each of the plurality of first doped regions and the semiconductor substrate,
the third electrode is spaced apart from the second electrode, and
the third direction is perpendicular to the plane of the semiconductor substrate.

18. The semiconductor device of claim 17, wherein
the third electrode overlaps at least portions of each of the plurality of first doped regions in the third direction.

19. The semiconductor device of claim 17, wherein
in the third direction, the third electrode overlaps at least portions of regions of the semiconductor substrate adjacent to the depletion region in the first direction.

20. A semiconductor device comprising:
an electrical stress protection circuit; and
an internal circuit,
wherein
the electrical stress protection circuit comprises
a plurality of bipolar junction transistors connecting an input pad and a ground electrode in parallel, and
a plurality of electrodes, each of the plurality of bipolar junction transistors comprises
a region of a semiconductor substrate configured as a base, the region of the semiconductor substrate having a first conductivity type,
a first doped region of a second conductivity type configured as a collector, and
a second doped region of the second conductivity type configured as an emitter
the plurality of electrodes include
a first electrode electrically connected to the input pad and the first doped region, and
a second electrode electrically connected to the ground electrode and the second doped region, and
the second electrode overlaps at least a portion of a depletion region of each of the plurality of bipolar junction transistors in a direction perpendicular to a plane of the semiconductor substrate.
